(19) United States
(12) Patent Application Publication
(10) Pub. No.: US 2016/0200213 A1
(43) Pub. Date: Jul. 14, 2016

(54) Bi-Directional Current Sensing Using Unipolar Sensors With Closed Loop Feedback

(71) Applicant: Ford Global Technologies, LLC, Dearborn, MI (US)

(72) Inventors: Christopher Wolf, South Bend, IN (US); Michael W. Degner, Novi, MI (US)

(21) Appl. No.: 14/595,269

(22) Filed: Jan. 13, 2015

(51) Int. Cl. B60L 11/18; G01K 13/00; G01R 15/20; B60W 20/00; G01R 31/36

(52) U.S. Cl. CPC B60L 11/1864; B60W 20/00; G01R 31/3658; G01R 15/205; G01K 13/00; Y10S 903/907

(57) ABSTRACT

A vehicle includes a ferromagnetic core having a winding, defining a gap, and configured to concentrate a net field in the gap. The vehicle also includes a controller programmed to flow a current in the winding such that an angle of the net field relative to a unipolar sensor in the gap is approximately zero and an intensity of the net field is at least twice that of a bi-directional field in the gap radiated from a conductor.

### TECHNICAL FIELD

This application generally relates to bi-directional current measurement using a unipolar sensor with closed loop feedback.

### BACKGROUND

A hybrid-electric vehicle includes a traction battery constructed of multiple battery cells in series and/or parallel. The traction battery provides power for vehicle propulsion and accessory features. Power is the product of two components: voltage and current. Hall Effect sensors are predominately used to monitor traction battery current due to its magnitude along with vehicular size and cost constraints.

### SUMMARY

A vehicle includes a ferromagnetic core assembly, a conductor, a unipolar sensor and a controller. The ferromagnetic core assembly defines a gap and has a winding configured to create a base magnetic field in the gap. The conductor couples a traction battery with an electric machine. The conductor radiates a bi-directional magnetic field in the gap. The unipolar sensor has a sensitivity range and is located within the gap. The unipolar sensor is configured to measure an intensity of the magnetic field in the gap. The controller is programmed to flow a current in the winding to drive an angle of the magnetic field towards zero. The flow of current in the winding is such that an intensity of the net magnetic field falls within the sensitivity range. A magnitude of the current is proportional to a torque of the electric machine, and a polarity of the current is indicative of a direction of traction battery current flow.

A method of controlling a traction battery includes outputting a current to a winding to induce a base magnetic field in a ferromagnetic core having a conductor passing through a center thereof, and adjusting, via closed loop feedback, the current such that a net magnetic field is generally maintained within a sensitivity range of a unipolar sensor operatively arranged with the ferromagnetic core. A lower threshold of the sensitivity range is greater than twice a maximum absolute value of a magnitude of an induced field from a bi-directional current expected to flow through the conductor. The method further includes operating the traction battery based on the current.

A vehicle includes a ferromagnetic core having a winding, defining a gap, and configured to concentrate a net field in the gap. The vehicle also includes a controller programmed to flow a current in the winding such that an angle of the net field relative to a unipolar sensor in the gap is approximately zero and an intensity of the net field is at least twice that of a bi-directional field in the gap radiated from a conductor.

### BRIEF DESCRIPTION OF THE DRAWINGS

FIG. 1 is an exemplary diagram of a hybrid vehicle illustrating typical drivetrain and energy storage components.

FIG. 2 is an exemplary diagram of a battery pack controlled by a Battery Energy Control Module.

FIG. 3 is an exemplary diagram of a unipolar magnetic sensor in a flux concentrating core employing closed loop feedback.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the present invention. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The control of a hybrid electric automotive system is based on multiple factors including a current flowing from a traction battery to an electric machine. The current may flow from the battery to the electric machine to propel the vehicle. Likewise, the current may flow from the electric machine to the battery to charge the battery. A challenge to controlling the battery and electric machine is measuring the current in both magnitude and direction. Traditionally the use of a bi-directional sensor element is used to allow determination of the direction of the current flow. Here the use of a unipolar sensor, having the capability of measuring magnitude but not direction, is configured with a core assembly in a way to measure both magnitude and direction. The control of torque in the electric machine requires accurate measurement of multiple parameters including a measurement of an electric machine current flow. For automotive use, a current sensor must meet requirements for accuracy along with size and robustness requirements. Emerging technologies can be applied to meet these requirements and reduce the cost when compared to present current sensors.

Sensor technology may utilize different methods to measure current. One type of sensor utilizes a change in resistance of a material when in the presence of a magnetic field or field, called the Magnetoresistive Effect, (MR or MR-effect). MR sensors have become practically possible through advancements in thin-film technology and provide a cost effective means of measuring a magnetic field. The magnetic field may be induced by a current flowing in a conductor. The term MR sensor is a collective term for sensors based on a range of different, but related physical principles. All MR sensors operate by changing an electrical resistance of the sensor due to the influence of a magnetic field. However, different sensor structures allow for multiple characteristics to be determined including a magnetic field angle, magnetic field strength or a magnetic field gradient. For example, Anisotropic Magnetoresistive (AMR) effects occur in ferromagnetic materials, in which an impedance changes based on a direction of an applied magnetic field. Tunnel Magnetoresistive (TMR) effects change resistance in response to an angle of a magnetization direction in each of two layers separated by a tunnel barrier (insulator). Giant Magnetoresistive (GMR) effects occur in layer systems with at least two ferromagnetic layers and a single non-magnetic, metallic intermediate layer. A change in resistance is based on the applied field and the angle of the field. When the angle of the field is at 0 degrees, the change in resistance is high and when the angle is at 90 degrees, the change in resistance is low. Therefore, when the direction of the field is perpendicular to the axis of sensitivity the change in resistance is low. Although the change in resistance is affected by the angle, the change in resistance is generally equal when at 0 degrees and 180 degrees or parallel, and does not depend on the direction of the current.

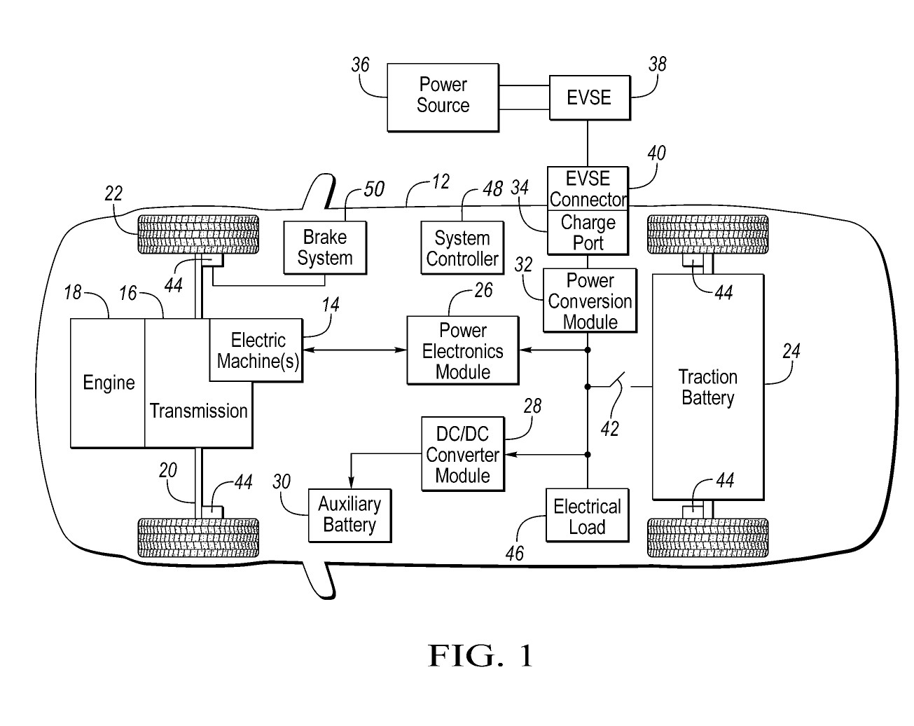

FIG. 1 depicts a typical plug-in hybrid-electric vehicle (PHEV). A typical plug-in hybrid-electric vehicle 12 may comprise one or more electric machines 14 mechanically connected to a hybrid transmission 16. The electric machines 14 may be capable of operating as a motor or a generator. In addition, the hybrid transmission 16 is mechanically connected to an engine 18. The hybrid transmission 16 is also mechanically connected to a drive shaft 20 that is mechanically connected to the wheels 22. The electric machines 14 can provide propulsion and deceleration capability when the engine 18 is turned on or off. The electric machines 14 also act as generators and can provide fuel economy benefits by recovering energy that would normally be lost as heat in the friction braking system. The electric machines 14 may also reduce vehicle emissions by allowing the engine 18 to operate at more efficient speeds and allowing the hybrid-electric vehicle 12 to be operated in electric mode with the engine 18 off under certain conditions.

A traction battery or battery pack 24 stores energy that can be used by the electric machines 14. A vehicle battery pack 24 typically provides a high voltage DC output. The traction battery 24 is electrically connected to one or more power electronics modules 26. One or more contactors 42 may isolate the traction battery 24 from other components when opened and connect the traction battery 24 to other components when closed. The power electronics module 26 is also electrically connected to the electric machines 14 and provides the ability to bi-directionally transfer energy between the traction battery 24 and the electric machines 14. For example, a typical traction battery 24 may provide a DC voltage while the electric machines 14 may operate using a three-phase AC current. The power electronics module 26 may convert the DC voltage to a three-phase AC current for use by the electric machines 14. In a regenerative mode, the power electronics module 26 may convert the three-phase AC current from the electric machines 14 acting as generators to the DC voltage compatible with the traction battery 24. The description herein is equally applicable to a pure electric vehicle. For a pure electric vehicle, the hybrid transmission 16 may be a gear box connected to an electric machine 14 and the engine 18 may not be present.

In addition to providing energy for propulsion, the traction battery 24 may provide energy for other vehicle electrical systems. A typical system may include a DC/DC converter module 28 that converts the high voltage DC output of the traction battery 24 to a low voltage DC supply that is compatible with other vehicle loads. Other high-voltage loads 46, such as compressors and electric heaters, may be connected directly to the high-voltage without the use of a DC/DC converter module 28. The low-voltage systems may be electrically connected to an auxiliary battery 30 (e.g., 12V battery).

The vehicle 12 may be an electric vehicle or a plug-in hybrid vehicle in which the traction battery 24 may be recharged by an external power source 36. The external power source 36 may be a connection to an electrical outlet that receives utility power. The external power source 36 may be electrically connected to electric vehicle supply equipment (EVSE) 38. The EVSE 38 may provide circuitry and controls to regulate and manage the transfer of energy between the power source 36 and the vehicle 12. The external power source 36 may provide DC or AC electric power to the EVSE 38. The EVSE 38 may have a charge connector 40 for plugging into a charge port 34 of the vehicle 12. The charge port 34 may be any type of port configured to transfer power from the EVSE 38 to the vehicle 12. The charge port 34 may be electrically connected to a charger or on-board power conversion module 32. The power conversion module 32 may condition the power supplied from the EVSE 38 to provide the proper voltage and current levels to the traction battery 24. The power conversion module 32 may interface with the EVSE 38 to coordinate the delivery of power to the vehicle 12. The EVSE connector 40 may have pins that mate with corresponding recesses of the charge port 34. Alternatively, various components described as being electrically connected may transfer power using a wireless inductive coupling.

One or more wheel brakes 44 may be provided for decelerating the vehicle 12 and preventing motion of the vehicle 12. The wheel brakes 44 may be hydraulically actuated, electrically actuated, or some combination thereof. The wheel brakes 44 may be a part of a brake system 50. The brake system 50 may include other components to operate the wheel brakes 44. For simplicity, the figure depicts a single connection between the brake system 50 and one of the wheel brakes 44. A connection between the brake system 50 and the other wheel brakes 44 is implied. The brake system 50 may include a controller to monitor and coordinate the brake system 50. The brake system 50 may monitor the brake components and control the wheel brakes 44 for vehicle deceleration. The brake system 50 may respond to driver commands and may also operate autonomously to implement features such as stability control. The controller of the brake system 50 may implement a method of applying a requested brake force when requested by another controller or sub-function.

One or more electrical loads 46 may be connected to the high-voltage bus. The electrical loads 46 may have an associated controller that operates and controls the electrical loads 46 when appropriate. Examples of electrical loads 46 may be a heating module or an air-conditioning module.

The various components discussed may have one or more associated controllers to control and monitor the operation of the components. The controllers may communicate via a serial bus (e.g., Controller Area Network (CAN), Ethernet, Flexray) or via discrete conductors. A system controller 48 may be present to coordinate the operation of the various components.

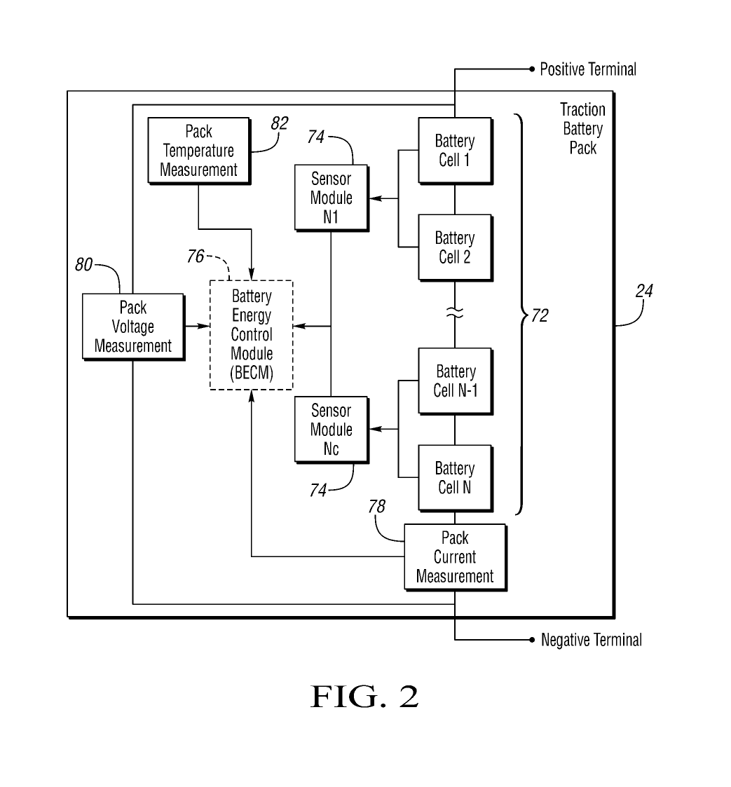

A traction battery 24 may be constructed from a variety of chemical formulations. Typical battery pack chemistries may be lead acid, nickel-metal hydride (NIMH) or Lithium-Ion. FIG. 2 shows a typical traction battery pack 24 in a series configuration of N battery cells 72. Other battery packs 24, however, may be composed of any number of individual battery cells connected in series or parallel or some combination thereof. A battery management system may have a one or more controllers, such as a Battery Energy Control Module (BECM) 76 that monitors and controls the performance of the traction battery 24. The BECM 76 may include sensors and circuitry to monitor several battery pack level characteristics such as pack current 78, pack voltage 80 and pack temperature 82. The BECM 76 may have non-volatile memory such that data may be retained when the BECM 76 is in an off condition. Retained data may be available upon the next key cycle.

In addition to the pack level characteristics, there may be battery cell level characteristics that are measured and monitored. For example, the terminal voltage, current, and temperature of each cell 72 may be measured. The battery management system may use a sensor module 74 to measure the battery cell characteristics. Depending on the capabilities, the sensor module 74 may include sensors and circuitry to measure the characteristics of one or multiple of the battery cells 72. The battery management system may utilize up to N_{c} sensor modules or Battery Monitor Integrated Circuits (BMIC) 74 to measure the characteristics of all the battery cells 72. Each sensor module 74 may transfer the measurements to the BECM 76 for further processing and coordination. The sensor module 74 may transfer signals in analog or digital form to the BECM 76. In some embodiments, the sensor module 74 functionality may be incorporated internally to the BECM 76. That is, the sensor module 74 hardware may be integrated as part of the circuitry in the BECM 76 and the BECM 76 may handle the processing of raw signals.

The BECM 76 may include circuitry to interface with the one or more contactors 42. The positive and negative terminals of the traction battery 24 may be protected by contactors 42.

Battery pack state of charge (SOC) gives an indication of how much charge remains in the battery cells 72 or the battery pack 24. The battery pack SOC may be output to inform the driver of how much charge remains in the battery pack 24, similar to a fuel gauge. The battery pack SOC may also be used to control the operation of an electric or hybrid-electric vehicle 12. Calculation of battery pack SOC can be accomplished by a variety of methods. One possible method of calculating battery SOC is to perform an integration of the battery pack current over time. This is well-known in the art as ampere-hour integration.

Battery SOC may also be derived from a model-based estimation. The model-based estimation may utilize cell voltage measurements, the pack current measurement, and the cell and pack temperature measurements to provide the SOC estimate.

The BECM 76 may have power available at all times. The BECM 76 may include a wake-up timer so that a wake-up may be scheduled at any time. The wake-up timer may wake up the BECM 76 so that predetermined functions may be executed. The BECM 76 may include non-volatile memory so that data may be stored when the BECM 76 is powered off or loses power. The non-volatile memory may include Electrical Eraseable Programmable Read Only Memory (EEPROM) or Non-Volatile Random Access Memory (NVRAM). The non-volatile memory may include FLASH memory of a microcontroller.

A GMR sensor is based on the GMR-effect, wherein the resistance of the sensor is a function of the strength or magnitude and angle of the magnetic field in which it exists. In operation, an electrical current flowing through a conductor induces a corresponding magnetic field. A measurement of this magnetic field can, therefore, be used to provide information about the state of the electrical current through the conductor.

The GMR sensor is generally a unipolar device, in that it is unable to distinguish the direction of magnetic flux. As the electric drive in an electrified power train requires bi-directional current sensing capabilities, a method is disclosed that enables a direction or angle of the magnetic field to be determined using a unipolar sensor. The direction or angle of the magnetic field is in relation to an axis of sensitivity of the unipolar sensor in which a zero degree angle is parallel to the axis of sensitivity, 90 degrees is perpendicular to the axis of sensitivity, and 180 degrees is parallel to the axis of sensitivity with the field direction opposite to the zero degree field. Additionally, the linear range of the sensor is limited and likewise a method is disclosed that enables the measurement of a large change in magnetic field by a sensor with a limited operational range.

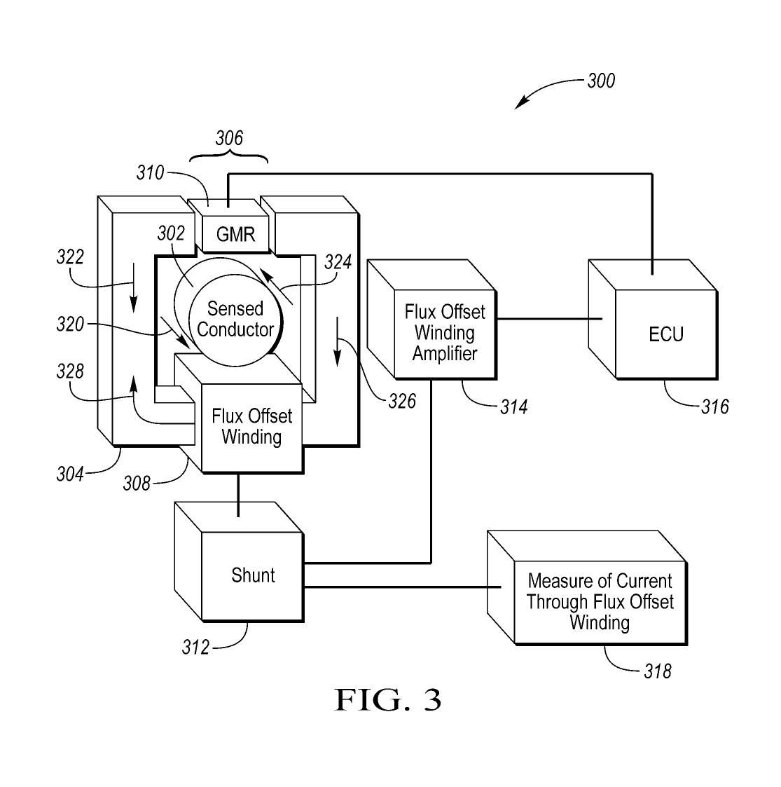

A ferromagnetic core is used to concentrate the magnetic flux created by the electrical current through the conductor being measured. The core has a gap on one side to allow placement of a GMR sensor. As the GMR is directly in the path of the magnetic flux, and the core focuses the majority of the flux through that path, the sensitivity of the GMR to the electrical current through the conductor is increased. The concept is shown graphically in FIG. 3.

Wrapped around the core is a winding that can create a magnetic flux through the core, creating an offset or base magnetic field. A closed-loop controller can regulate the current through the winding to maintain a net flux in the core at generally a constant level. This ensures that the net flux through the core and GMR sensor is within the linear range of the GMR sensor. By measuring the current through the offset winding, the current through the sensed conductor can be calculated. This measurement may be accomplished in many ways including the use of a shunt in series with the winding in which a voltage across the shunt is measured.

FIG. 3 is an exemplary diagram of a bi-directional current measuring system 300. A conductor 302 capable of carrying a current is coupled to a ferroelectric core 304. The conductor 302 being capable of carrying a bi-directional current may then induce a bi-directional field in the ferroelectric core 304. The ferroelectric core 304 may be in the shape of a “C”, toroidal, or other suitable shape. The conductor 302 may be coupled via placement in proximity to the ferroelectric core 304 or the conductor may pass through an opening defined by the core 304. The conductor 302 may be made of a metal such as copper or aluminum, a metal alloy, a conductive composite or plated material. The conductor 302 may be configured as wire, cable, ribbon, cable or other suitable structure. The electromagnetic core 304 may be a ferromagnetic material such as metals and alloys of iron, nickel and cobalt, and some rare earth metal compounds. The electromagnetic core 304 may generally surround the conductor 302 having a gap 306 and a winding 308 as shown in FIG. 3. The core 304 and gap 306 may be sized to accommodate a magnetic sensor 310 such as a giant magnetoresistance (GMR) sensor, a tunneling magnetoresistance (TMR) sensor, or other suitable unipolar sensor. The winding 308 is configured to carry an electric current inducing a magnetic field in the core 304 in addition to the magnetic field induced by the conductor 302. The electric current in the winding 308 is detected by a voltage across a resistive shunt 312. The current in the winding is generated by a current source or amplifier 314. The amplifier 314 converts a signal from an ECU or controller 316 to a current. The current is based on a measured magnetic flux in the core 304. The measured magnetic flux in the core may be controlled by a closed loop mechanism such as an analog feedback circuit or a digital feedback circuit. The GMR 310 operates by changing resistance in response to a change in magnetic flux encompassing the GMR 310.

A measurement of current obtained from the GMR sensor including the offset winding 308 and closed-loop control mechanism, and configured as shown in FIG. 3, may be used to control a torque of a shaft in the electric motor 14 in hybrid/battery electric vehicles as well as in heavier traction applications such as electric locomotives. The measurement of current can also be used to estimate the torque produced by the electric motor 14. In a vehicle, the measurement of current can also be used to estimate and control vehicle speed, via the measurement and control of electrical current/torque. The measurement of current can also be used to measure and control the flow of power between the battery 24 on a hybrid/full electric vehicle and the various power converters 26,28 and electric loads 46 on the vehicle. The measurement of current from a charging source 36 can also be used to control the recharging of the battery 24 through the power conversion module 32.

The ECU 316 controls the current magnitude through the offset winding via a signal sent to the amplifier 314. The current flowing through the winding 308 creates a base or offset magnetic field 328 in the core 304. A current flowing in the conductor 302 in the direction 320 induces a magnetic field 322 in the core 304, and a current flowing in the conductor 302 in the direction 324 induces a magnetic field 326 in the core 304. For example, the system may be designed such that the offset field 328 is greater than twice the absolute value of a maximum of the induced field (322 and 324). In this example, a current flowing in the conductor in the direction of 324 inducing a field 326 may require a small current to flow in the winding 308 such that a small offset field 328 is generated. However, a current flowing in the conductor in the direction of 320 inducing a field 322 may require a greater current to flow in the winding 308 such that a large offset field 328 is required to offset the field 322. The current flowing in the winding 308 induces a field such that when added with the induced field from the current flowing in the conductor 302, a net flux in the core 304 and across the sensor 310 is maintained within the operational limits of the sensor 310. This configuration allows for the measuring of a change in an induced field in which the induced field change is larger than the operational range of the sensor 310. As the current through the offset winding 308 is controlled to create a constant net flux through the sensor 310, the current in the offset winding 308 will have a known relationship with the current flowing in the sensed conductor 302 and can be used to calculate the current through the sensed conductor 302. The known relationship may include a function such as linear, weighted, or curvilinear function.

An alternative embodiment may include a second ferromagnetic core assembly. The second ferromagnetic core assembly or core assembly may include a second gap wherein a second unipolar sensor may be located. The second core assembly may be configured to measure an ambient magnetic field or field. The ambient magnetic field or ambient field may be generated by a vehicle electric system, an electric system outside the vehicle or may occur due to the magnetic properties of the earth. Another alternative embodiment may include a temperature sensor coupled to the unipolar sensor. An accuracy of the unipolar sensor may change in relation to operating parameters. Operating parameter include voltage, time, life, construction, and temperature. Each operating parameter may include a calibration coefficient based on theoretical or measured data. For example, a change in temperature of the unipolar sensor may cause change in the accuracy based on a temperature drift of the unipolar sensor. Based on a measured operating parameter, the output of the unipolar sensor may be offset by the coefficient of the improve accuracy.

The processes, methods, or algorithms disclosed herein can be deliverable to/implemented by a processing device, controller, or computer, which can include any existing programmable electronic control unit or dedicated electronic control unit. Similarly, the processes, methods, or algorithms can be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes may include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and can be desirable for particular applications.

What is claimed is:

1. A vehicle comprising:
a ferromagnetic core assembly defining a gap and having a winding configured to create a base magnetic field in the gap;
a conductor coupling a traction battery with an electric machine configured to radiate a bi-directional magnetic field in the gap;
a unipolar sensor, having a sensitivity range, located within the gap and configured to measure an intensity of a net magnetic field in the gap; and
a controller programmed to flow a current in the winding to drive an angle of the net magnetic field towards zero such that an intensity of the net magnetic field falls within the sensitivity range, wherein a magnitude of the current is proportional to a torque of the electric machine and a polarity of the current is indicative of a direction of traction battery current flow.

2. The vehicle of claim 1, wherein the unipolar sensor is a giant magnetoresistance (GMR) sensor.

3. The vehicle of claim 1, wherein the net magnetic field in the gap is formed by the bi-directional magnetic field and the base magnetic field.

4. The vehicle of claim 1, wherein the bi-directional magnetic field is induced by a bi-directional current in the conductor.

5. The vehicle of claim 1 further comprising a temperature sensor coupled to the unipolar sensor, wherein the controller is further programmed to monitor a temperature of the sensor and adapt the current flowing in the winding based on the temperature and a temperature drift of the unipolar sensor.

6. The vehicle of claim 1 further comprising a second ferromagnetic core assembly, having a second gap, and a second unipolar sensor located within the second gap configured to measure an ambient magnetic field generated by an electric system in the vehicle.

7. The vehicle of claim 6, wherein the controller is further programmed to drive a current in the winding to compensate for the ambient magnetic field.

8. The vehicle of claim 1, wherein the ferromagnetic core assembly includes a toroid and the conductor passes through an axis of the toroid.

9. A method of controlling a traction battery comprising:
outputting a current to a winding to induce a base magnetic field in a ferromagnetic core having a conductor passing through a center thereof;
adjusting, via closed loop feedback, the current such that a net magnetic field is generally maintained within a sensitivity range of a unipolar sensor operatively arranged with the ferromagnetic core, wherein a lower threshold of the sensitivity range is greater than twice a maximum absolute value of a magnitude of an induced field from a bi-directional current expected to flow through the conductor; and
operating the traction battery based on the current.

10. The method of claim 9, wherein the unipolar sensor is a giant magnetoresistance (GMR) sensor.

11. The method of claim 9 further comprising monitoring a temperature of the sensor and adapting the current based on the temperature and a temperature drift of the unipolar sensor.

12. The method of claim 9 further comprising measuring an ambient magnetic field generated by a vehicle electric system including the traction battery and further adjusting the current in the winding to compensate for the ambient magnetic field.

13. A vehicle comprising:
a ferromagnetic core having a winding, defining a gap, and configured to concentrate a net field in the gap; and
a controller programmed to flow a current in the winding such that an angle of the net field relative to a unipolar sensor in the gap is approximately zero and an intensity of the net field is at least twice that of a bi-directional field in the gap radiated from a conductor.

14. The vehicle of claim 13, wherein the net field in the gap is formed by the bi-directional field and a base field induced by the current in the winding.

15. The vehicle of claim 13, wherein the unipolar sensor is a giant magnetoresistance (GMR) sensor.

16. The vehicle of claim 13 further comprising a temperature sensor coupled to the unipolar sensor, wherein the controller is further programmed to monitor a temperature of the sensor and adapt the current flowing in the winding based on the temperature and a temperature drift of the unipolar sensor.

17. The vehicle of claim 13 further comprising a second ferromagnetic core assembly having a second gap, and a second unipolar sensor located within the second gap configured to measure an ambient field generated by an electric system in the vehicle.

18. The vehicle of claim 17, wherein the controller is further programmed to drive a current in the winding to compensate for the ambient field.
